(19) United States
(12) Patent Application Publication
(10) Pub. No.: US 2023/0135496 A1
(43) Pub. Date: May 4, 2023

(54) TEST METHOD AND SYSTEM

(71) Applicant: REALTEK SEMICONDUCTOR CORPORATION, HSINCHU (TW)

(72) Inventors: CHIA HAN LIN, HSINCHU (TW); MENG AN KUO, HSINCHU (TW); ZONG-DA HUANG, HSINCHU (TW)

(21) Appl. No.: 18/048,201

(22) Filed: Oct. 20, 2022

(30) Foreign Application Priority Data
Nov. 2, 2021 (TW) 110140781

(51) Int. Cl. G01R 31/28

(52) U.S. Cl. CPC G01R 31/2837; G01R 31/2831

(57) ABSTRACT

A test method is configured to test a chip on a circuit under test, wherein the circuit under test further includes a DC-DC converter. The test method includes the operations of: generating a test pulse signal; filtering the test pulse signal to generate a first test DC voltage to the DC-DC converter, wherein the DC-DC converter transforms the first test DC voltage to a second test DC voltage and transmits the second test DC voltage to the chip; and extracting an output signal of the chip to determine a performance of the chip, wherein the chip generates the output signal according to the second test DC voltage.

### CROSS-REFERENCE TO RELATED APPLICATIONS

This application claims the benefit of priority to Patent Application No. 110140781, filed in Taiwan on Nov. 2, 2021, which is incorporated by reference in its entirety.

### TECHNICAL FIELD

The present application relates to a test method and a test system, particularly to a test method and a test system for testing chips on circuits.

### BACKGROUND

When a chip in an integrated circuit is to be tested so as to check whether it has qualified performance, a supply voltage of the chip is adjusted within the operable voltage range to check whether the chip operates properly. Regardless of the voltage value applied to the chip within the operable voltage range, the operator needs to manually adjust the supply voltage of the chip, which is labor-intensive and time-consuming. Therefore, how to increase the efficiency of wafer testing in integrated circuits has become an important issue in this field.

### SUMMARY OF THE INVENTION

An aspect of the present disclosure provides a test method configured to a chip on a circuit under test. The circuit under test further includes a DC-DC converter. The test method includes steps of: generating a test pulse signal; filtering the test pulse signal to generate a first test DC voltage to the DC-DC converter, wherein the DC-DC converter converts the first test DC voltage into a second test DC voltage and transmits the second test DC voltage to the chip; and extracting an output signal of the chip to determine a performance of the chip, wherein the chip generates the output signal according to the second test DC voltage.

Another aspect of the present disclosure provides a test system configured to test a chip on a circuit under test. The circuit under test further comprises a DC-DC converter. The test system includes a processor, a filter circuit, and a control interface. The processor is configured to generate a test pulse signal. The filter circuit is configured to filter the test pulse signal to generate a first test DC voltage to the DC-DC converter, wherein the DC-DC converter generates a second test DC voltage according to the first test DC voltage and transmits the second test DC voltage to the chip. The control interface is configured to extract an output signal of the chip to determine a performance of the chip, wherein the chip generates the output signal according to the second test DC voltage.

Compared to the conventional technology, the test method and test system of the present disclosure generate DC voltages with accurate voltage levels using a processor and a filter circuit, and supply the DC voltages to the chip. In addition to increasing the accuracy of the test, it also improves the efficiency of the test.

### BRIEF DESCRIPTION OF THE DRAWINGS

Various aspects of the present application can best be understood upon reading the detailed description below and accompanying drawings. It should be noted that the various features in the drawings are not drawn to scale in accordance with standard practice in the art. In fact, the size of some features may be deliberately enlarged or reduced for the purpose of discussion.

FIG. 1 is a schematic diagram illustrating a test system according to some embodiments of the present disclosure.

FIG. 2 is a schematic diagram illustrating a correspondence between duty cycle and voltage according to some embodiments of the present disclosure.

FIG. 3 is a schematic diagram illustrating a filter circuit according to some embodiments of the present disclosure.

FIG. 4 is a flow chart of a test method according to some embodiments of the present disclosure.

### DETAILED DESCRIPTION

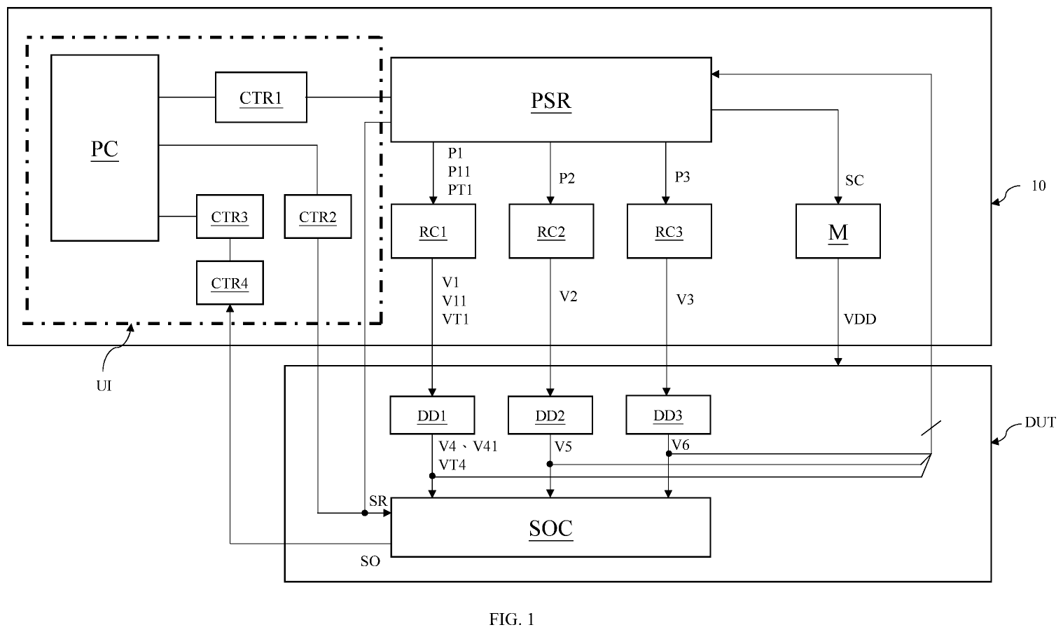

FIG. 1 is a schematic diagram illustrating a test system 10 according to some embodiments of the present disclosure. The test system 10 is configured to test the performance of a chip SOC on a circuit under test DUT. The test system 10 is configured to provide different DC voltages to the circuit under test DUT and extract the output signal VO of the circuit under test DUT to determine the performance of the chip SOC.

The test system 10 is configured to generate a DC voltage V1, a DC voltage V2 and a DC voltage V3 to the circuit under test DUT. The circuit under test DUT converts the DC voltages V1-V3 into a DC voltage V4, a DC voltage V5 and a DC voltage V6, respectively, via a DC-DC converter DD1, a DC-DC converter DD2 and a DC-DC converter DD3. The chip SOC generates an output signal VO according to the operation of the DC voltages V4-V6. For the sake of brevity, the DC voltage will be referred to as “voltage” hereinbelow.

The chip SOC includes different power domains, and hence, each power domain should be supplied by different voltages. The DC-DC converters DD1-DD3 supply to different power domains in the chip SOC, respectively. In some embodiments, the core voltage, the central processing unit and the memory on the chip SOC belong to different power domains, respectively, whereas the DC-DC converter DD1 is a core voltage DC-DC converter, the DC-DC converter DD2 is a central processing unit DC-DC converter, and the DC-DC converter DD3 is a dual-channel dynamic random access memory DC-DC converter.

The test system 10 includes a processor PSR, a filter circuit RC1, a filter circuit RC2, a filter circuit RC3, a control interface UI and a power resistor M.

The processor PSR is configured to generate a control signal SC to the power resistor M, and generate a pulse signal P1, a pulse signal P2 and a pulse signal P3, to transmit the same to the filter circuit RC1, the filter circuit RC2 and the filter circuit RC3, respectively.

The power resistor M provides reference voltage VDD to the circuit under test DUT according to the control signal SC. Specifically, the power resistor M is configured to provide the reference voltage VDD to the DC-DC converters DD1-DD3 for operation.

The filter circuit RC1 is configured to filter the pulse signal P1 to generate a voltage V1 and transmit the same to the DC-DC converter DD1. The duty cycle of the pulse signal P1 is related to a voltage level of the voltage V1 generated by the filter circuit RC1. In some embodiments, lower duty cycle of the pulse signal P1 corresponds to higher voltage level of the voltage V1. The voltage V1 and the voltage V4 can be the same or different. The operations of the filter circuit RC2, the filter circuit RC3, the DC-DC converter DD2 and the DC-DC converter DD3 are similar to those of the filter circuit RC1 and the DC power converter DD1 and are not repeated herein.

Take the DC-DC converter DD1 as an example, generally speaking, the ratio between the voltage V1 and the voltage V4 is substantially fixed. However, due to some process factors or other external conditions, the ratio between the voltage V1 and the voltage V4 may deviate from the original fixed value. When such an offset occurs, the voltage V4 received by the chip SOC may deviate from a predetermined voltage level. The different voltage levels may cause the chip SOC to have different performances, thereby making the test results inaccurate.

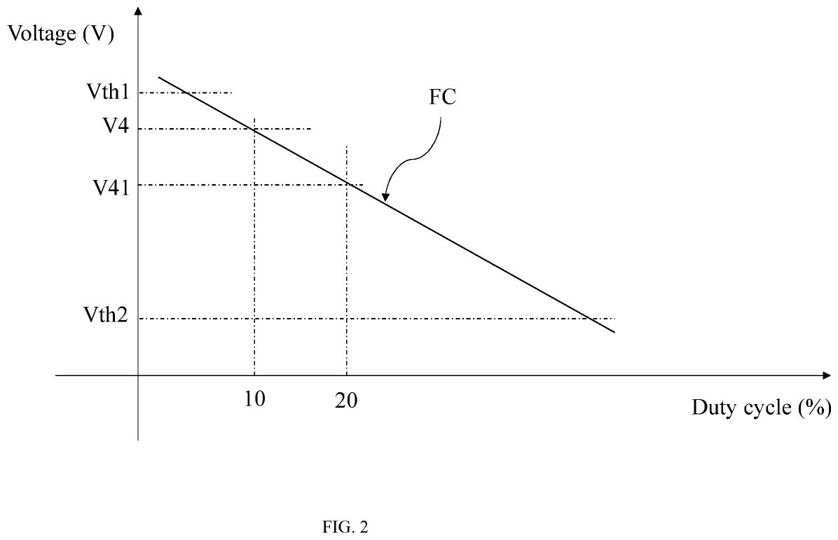

To avoid the above-mentioned deviation, the processor PSR is further configured to generate the pulse signal P1 and the pulse signal P11 to the filter circuit RC1 at different time points, respectively; the filter circuit RC1 filters the pulse signal P1 and the pulse signal P11 into the voltage V1 and the voltage V11, respectively; then, the DC-DC converter DD1 further converts the voltage V1 and the voltage V11 into the voltage V4 and the voltage V41, respectively, wherein the pulse signal P1 and the pulse signal P11 respectively have different duty cycles. The processor PSR is further configured to extract the voltage V4 and the voltage V41, and obtain a correspondence FC according to the pulse signal P1, the pulse signal P11, the voltage V4 and the voltage V41. Reference is also made to FIG. 2, the correspondence FC represents a function of the duty cycle of the pulse signal generated by the processor PSR and the voltage level of the voltage of the pulse signal passing through the DC-DC converter DD1. The processor PSR can control the duty cycle of the pulse signal P1 to obtain the voltage V4 having the desired voltage level according to the correspondence FC.

In some embodiments, the processor PSR performs an interpolation on the difference between the duty cycle of the pulse signal P1 and the duty cycle of the pulse signal P11 and the difference between the voltage V4 and the voltage V41, and obtains the correspondence FC according to the result of interpolation. However, the present disclosure is not limited to the computation of the interpolation, and various fitting methods are within the contemplated scope of the present disclosure.

In some embodiments, the duty cycle of the pulse signal P1 is 10%, and the duty cycle of the pulse signal P11 is 20%.

After the processor PSR obtains the correspondence FC, the voltage received by the chip SOC can be controlled accurately. In some embodiments, the above-mentioned operation of obtaining the correspondence FC is a calibration stage, and after obtaining the correspondence FC, the test system 10 can enter the test stage.

During the test stage, the processor PSR generates a test pulse signal PT1 to the filter circuit RC1. The filter circuit RC1 filters the test pulse signal PT1 according to the correspondence FC to generate a test voltage VT1 to the DC voltage converter DD1, then the DC-DC converter DD1 converts the test voltage VT1 into a test voltage VT4. The chip SOC receives the test voltage VT4 and generates the output signal VO according to the operation of the test voltage VT4. In some embodiments, the test voltage VT4 is equal to the upper limit Vth1 of the operating voltage of the chip SOC (such as the upper limit Vth1 of the operating voltage in FIG. 2). In some other embodiments, the test voltage VT4 is equal to the lower limit Vth2 of the operating voltage of the chip SOC (such as the lower limit Vth2 of the operating voltage in FIG. 2).

The operations of the filter circuit RC2, the filter circuit RC3, the DC-DC converter DD2 and the DC-DC converter DD3 in the test stage are similar to those of the filter circuit RC1 and the DC-DC converter DD1, and hence is not repeated herein.

In some embodiments, when the voltage received by the chip SOC is converted, the chip SOC needs to be reset. In some embodiments, the processor PSR is configured to generate a reset signal SR to the chip SOC to reset the control chip SOC. In some other embodiments, the test system 10 reset the chip SOC via the control interface UI.

In some embodiments, the control interface UI includes a computer PC having a USB interface. The computer PC connects to the processor PSR through the USB/RS232 connector CTR1. In some embodiments, the test pulse signal PT1 generated by the processor PSR can be controlled by the computer PC through the USB/RS232 connector CTR1. The computer PC further connects to the chip SOC through the USB/RS232 connector CTR2. In some embodiments, the reset signal SR is directly generated by the computer PC and is transmitted to the chip SOC through the USB/RS232 connector CTR2.

In some embodiments, the chip SOC is a chip in a display system, and the output signal SO generated by the chip SOC is a signal in the HDMI format. The computer PC connects to the chip SOC through the USB/RS232 connector CTR3 and the RS232/HDMI connector CTR4, and is configured to receive the output signal SO in the HDMI format, so as to determine the performance of the chip SOC using output signal SO during the test stage.

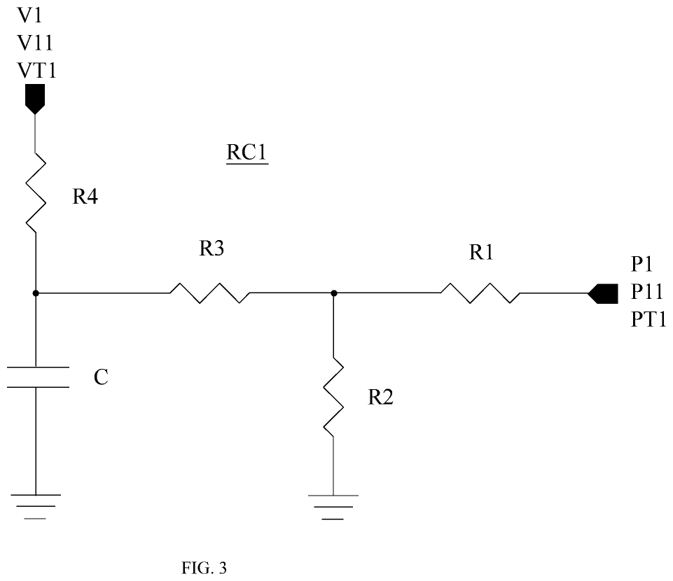

Reference is made to FIG. 3, which is a schematic diagram illustrating embodiments of the filter circuit RC1. The filter circuit RC1 includes a resistor R1, a resistor R2, a resistor R3, a resistor R4 and a capacitor C. The first terminal of the resistor R1 is coupled to the processor PSR shown in FIG. 1 and is configured to receive the pulse signal P1, the pulse signal P11 and test pulse signal PT1. The second terminal of the resistor R1 is coupled to the first terminal of the resistor R2 and the first terminal of the resistor R3. The second terminal of the resistor R2 is connected to the ground. The second terminal of the resistor R3 is coupled to the first terminal of the resistor R4 and the first terminal of the capacitor C. The second terminal of the capacitor C is connected to the ground. The second terminal of the resistor R4 is coupled to the DC-DC converter DD1 shown in FIG. 1 and is configured to output the voltage V1, the voltage V11 and the voltage VT1.

In some embodiments, the resistance of each of the resistor R2, the resistor R3 and the resistor R4 is 100K, 15.8K and 100K ohm, and the capacitance of the capacitor C is 22n farad. In some embodiments, the resistor R1 can be sort circuited; that is, the resistance of the resistor R1 is 0.

In some embodiments, the DC-DC converter DD2 and the DC-DC converter DD3 have a structure that is similar to that of the DC-DC converter DD1 except that the resistance and/or capacitance are different. For example, the DC-DC converter DD3 (applied in DDR) also includes the resistor R1, the resistor R2, the resistor R3, the resistor R4 and the capacitor C, and the resistance of each of the resistor R1, the resistor R2, the resistor R3 and the resistor R4 is 0, 100 K, 15.8 K and 1000 K, and the capacitance of the capacitor C is 22n farad.

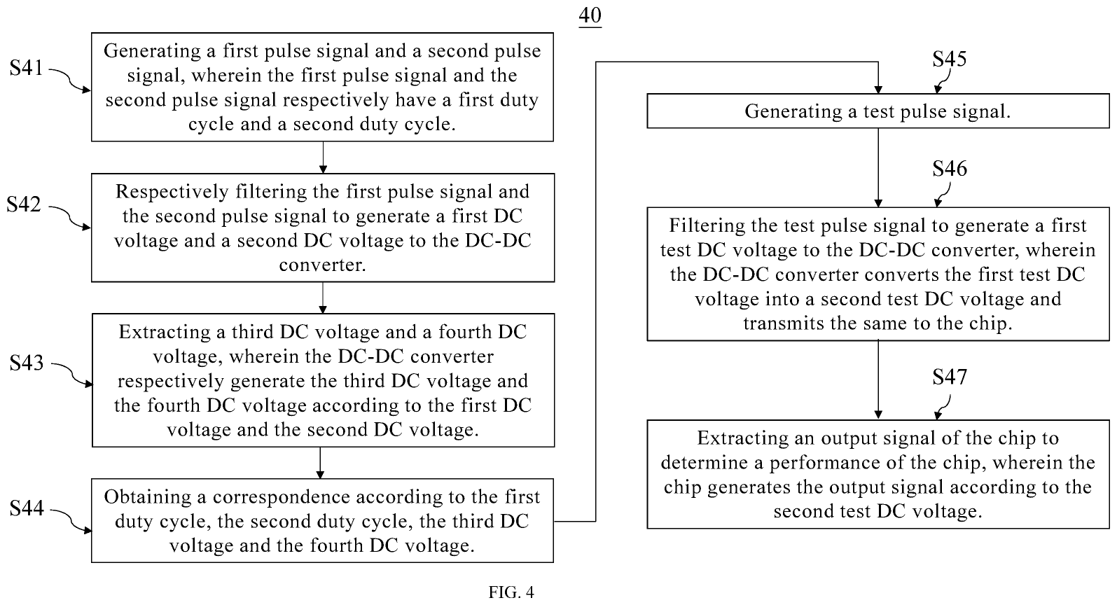

Reference is made to the flow chart of the test method 40 shown in FIG. 4. The test method 40 is configured to test the circuit under test DUT as shown in FIG. 1. In some embodiments, the test system 10 is configured to perform the test method 40 to test the circuit under test DUT. The test method 40 includes steps S41, S42, S43, S44, S45, S46 and S47. For the ease of understanding, the test method 40 is discussed by referencing the reference numerals used in FIGS. 1-3.

In Step S41, the pulse signal P1 and the pulse signal P11 (i.e., the first pulse signal and the second pulse signal) are generated, wherein the pulse signal P1 and the pulse signal P11 respectively have different duty cycles (i.e., the first duty cycle and the second duty cycle). In Step S42, the pulse signal P1 and the pulse signal P11 are filtered, respectively, to generate the voltage V1 and the voltage V11 (i.e., the first DC voltage and the second DC voltage) to the DC-DC converter DD1. In Step S43, the voltage V4 and the voltage V41 (i.e., the third DC voltage and the fourth DC voltage) are extracted, wherein the DC-DC converter DD1 generates the voltage V4 and the voltage V41, respectively, according to the voltage V1 and the voltage V11. In Step S44, the correspondence FC is obtained according to the duty cycle of the pulse signal P1 and the duty cycle of the pulse signal P11, the voltage V4 and the voltage V41. In Step S45, the test pulse signal PT1 is generated. In Step S46, the test pulse signal PT1 is filtered to generate the test voltage VT1 (i.e., the first test DC voltage) to the DC-DC converter DD1, wherein the DC-DC converter DD1 converts the test voltage VT1 into test voltage VT4 (i.e., the second test DC voltage) to the chip SOC. In Step S47, the output signal SO of the chip SOC is extracted to determine the performance of the chip SOC, wherein the chip SOC generates the output signal SO according to test voltage VT4.

The test method 40 is not limited to those shown in FIG. 4. In other embodiments, the test method 40 further includes at least one of the operations included in the embodiments shown in FIGS. 1-3.

In the present disclosure, any chip capable of outputting pulse signals having an adjustable duty cycle can be used as the processor PSR, and the tester can change the duty cycle of the pulse signal outputted from the processor PSR through any feasible control interface UI to change the DC voltage outputted to the chip SOC. Such an operation can improve the efficiency of the test. In addition, by properly programming the control interface UI, it is possible to automate the generation of DC voltages having different levels.

The foregoing description briefly sets forth the features of some embodiments of the present application so that persons having ordinary skill in the art more fully understand the various aspects of the disclosure of the present application. It will be apparent to those having ordinary skill in the art that they can easily use the disclosure of the present application as a basis for designing or modifying other processes and structures to achieve the same purposes and/or benefits as the embodiments herein. It should be understood by those having ordinary skill in the art that these equivalent implementations still fall within the spirit and scope of the disclosure of the present application and that they may be subject to various variations, substitutions, and alterations without departing from the spirit and scope of the present disclosure.

What is claimed is:

1. A test method, configured to test a chip on a circuit under test, wherein the circuit under test further comprises a DC-DC converter, comprising:
generating a test pulse signal;
filtering the test pulse signal to generate a first test DC voltage to the DC-DC converter, wherein the DC-DC converter converts the first test DC voltage into a second test DC voltage and transmits the second test DC voltage to the chip; and
extracting an output signal of the chip to determine a performance of the chip, wherein the chip generates the output signal according to the second test DC voltage.

2. The test method of claim 1, further comprising:
generating a first pulse signal and a second pulse signal, wherein the first pulse signal and the second pulse signal respectively have a first duty cycle and a second duty cycle;
respectively filtering the first pulse signal and the second pulse signal to generate a first DC voltage and a second DC voltage to the DC-DC converter;
extracting a third DC voltage and a fourth DC voltage, wherein the DC-DC converter respectively generate the third DC voltage and the fourth DC voltage according to the first DC voltage and the second DC voltage; and
obtaining a correspondence according to the first duty cycle, the second duty cycle, the third DC voltage and the fourth DC voltage.

3. The test method of claim 2, wherein the first duty cycle is 10%, and the second duty cycle is 20%.

4. The test method of claim 2, wherein the correspondence is a function of the first duty cycle and the third DC voltage.

5. The test method of claim 2, wherein the step of obtaining the correspondence according to the first duty cycle, the second duty cycle, the third DC voltage and the fourth DC voltage comprises:
performing an interpolation on a difference between the first duty cycle and the second duty cycle and a difference between the third DC voltage and the fourth DC voltage; and
obtaining the correspondence according to a result of the interpolation.

6. The test method of claim 2, wherein the test pulse signal is generated according to the correspondence.

7. The test method of claim 1, wherein a voltage value of the second test DC voltage is an upper limit of an operating voltage of the chip.

8. The test method of claim 1, wherein a voltage value of the second test DC voltage is a lower limit of an operating voltage of the chip.

9. The test method of claim 1, wherein the DC-DC converter is a core voltage DC-DC converter, a central processing unit DC-DC converter or a dual-channel dynamic random access memory DC-DC converter.

10. A test system, configured to test a chip on a circuit under test, wherein the circuit under test further comprises a DC-DC converter, comprising:
a processor, configured to generate a test pulse signal;
a filter circuit, configured to filter the test pulse signal to generate a first test DC voltage to the DC-DC converter, wherein the DC-DC converter generates a second test DC voltage according to the first test DC voltage and transmits the second test DC voltage to the chip; and
a control interface, configured to extract an output signal of the chip to determine a performance of the chip, wherein the chip generates the output signal according to the second test DC voltage.

11. The test system of claim 10, wherein
the processor is further configured to generate a first pulse signal and a second pulse signal, wherein the first pulse signal and the second pulse signal respectively have a first duty cycle and a second duty cycle,
the filter circuit is further configured to respectively filter the first pulse signal and the second pulse signal to generate a first DC voltage and a second DC voltage to the DC power converter, and
the processor is further configured to extract a third DC voltage and a fourth DC voltage, and obtain a correspondence according to the first duty cycle, the second duty cycle, the third DC voltage and the fourth DC voltage, wherein the DC-DC converter respectively generates the third DC voltage and the fourth DC voltage according to the first DC voltage and the second DC voltage.

12. The test system of claim 11, wherein the first duty cycle is 10%, and the second duty cycle is 20%.

13. The test system of claim 11, wherein the processor performs an interpolation on a difference between the first duty cycle and the second duty cycle and a difference between the third DC voltage and the fourth DC voltage, and obtains the correspondence according to a result of the interpolation.

14. The test system of claim 11, wherein the correspondence is a function of the first duty cycle and the third DC voltage.

15. The test system of claim 11, wherein the processor generates the test pulse signal according to the correspondence.

16. The test system of claim 11, wherein a voltage value of the second test DC voltage is an upper limit of an operating voltage of the chip.

17. The test system of claim 11, wherein a voltage value of the second test DC voltage is a lower limit of an operating voltage of the chip.

18. The test system of claim 10, wherein the DC-DC converter is a core DC-DC converter, a central processing unit DC-DC converter or a dual-channel dynamic random access memory DC-DC converter.

19. The test system of claim 10, further comprising:
a power resistor, configured to provide a reference voltage to the circuit under test.

20. The test system of claim 10, wherein the filter circuit comprises:
a first resistor;
a second resistor;
a third resistor, wherein a first terminal of the first resistor is connected to the ground, a second terminal of the first resistor is coupled to a first terminal the second resistor, a second terminal of the second resistor is coupled to a first terminal of the third resistor, wherein the second terminal of the first resistor and the first terminal of the second resistor is configured to receive the test pulse signal; and
a capacitor, wherein a first terminal of the capacitor is coupled to the second terminal of the second resistor and the first terminal of the third resistor, and a second terminal of the capacitor is connected to the ground,
wherein a second terminal of the third resistor is configured to output the first test DC voltage.
